(19) United States
(12) Patent Application Publication
(10) Pub. No.: US 2026/0182117 A1
(43) Pub. Date: Jun. 25, 2026

(54) LIGHT EMITTING DISPLAY APPARATUS

(71) Applicant: LG Display Co., Ltd., Seoul (KR)

(72) Inventors: DoHeon Kim, Paju-si (KR); YuSok Lim, Paju-si (KR)

(73) Assignee: LG Display Co., Ltd., Seoul (KR)

(21) Appl. No.: 19/399,134

(22) Filed: Nov. 24, 2025

(30) Foreign Application Priority Data
Dec. 23, 2024 (KR) 10-2024-0194773

(51) Int. Cl. H10H 29/49; H10D 86/40; H10D 86/60; H10H 29/32

(52) U.S. Cl. CPC H10H 29/49; H10H 29/32; H10D 86/441; H10D 86/60

(57) ABSTRACT

A light emitting display apparatus may include a substrate including a display area in which a plurality of subpixels, each comprising a pixel electrode, an emission layer, and a common electrode, are disposed, and a non-display area surrounding the display area, a gate driving circuit disposed in the non-display area and configured to drive a plurality of gate lines disposed in the display area, a first low-potential voltage line disposed in the non-display area and surrounding the display area, and a second low-potential voltage line disposed between the first low-potential voltage line and the gate driving circuit in the non-display area, the first low-potential voltage line and the second low-potential voltage line may be electrically connected to the common electrode.

### CROSS-REFERENCE TO RELATED APPLICATION

This application claims the benefit of and priority to Korean Patent Application No. 10-2024-0194773, filed in the Republic of Korea on Dec. 23, 2024, the entirety of which is incorporated herein by reference for all purposes.

### BACKGROUND

### Technical Field

The present disclosure relates to a light emitting display apparatus.

### Description of the Related Art

With the advancement of the information age, the demand for a display apparatus for displaying an image has increased in various forms. Therefore, various types of display apparatuses, such as a liquid crystal display (LCD) apparatus, an organic light emitting display (OLED) apparatus, a micro light emitting diode (LED) display apparatus, and a quantum dot display (QD) apparatus, have been recently used.

The display device is utilized in various fields, and as its application areas and purposes are gradually expanding, the size of the display panel is being developed in both larger and smaller scales. To enhance the efficiency of the manufacturing process, small and large display panels are mainly manufactured using the same mother substrate. For example, in the case of a small display device, a plurality of display panels may be simultaneously formed on a mother substrate and then separated into individual display panels through a cutting process or a scribing process to be manufactured as respective display devices.

### SUMMARY

However, during the cutting process or the scribing process for separating the display panels, electrostatic discharge (ESD), which is a momentarily high voltage, may occur. Such electrostatic discharge may damage a gate in panel (GIP) circuit embedded in a bezel region of the display panel, thereby causing malfunction in driving the GIP circuit. To reduce the influence of the electrostatic discharge, expanding the bezel region may be considered. However, since the bezel region is a non-display area where no input image is displayed, expanding the area may deteriorate the aesthetics and reduce the visibility of a miniaturized or relatively small display device.

One or more embodiments of the present disclosure may provide a light emitting display apparatus capable of improving the reliability of the display panel by blocking the inflow of electrostatic discharge occurring during the cutting process or the scribing process of the display panel or by increasing the inflow path, thereby reducing a malfunction in driving the GIP circuit of the display panel.

One or more embodiments of the present disclosure may provide a light emitting display apparatus capable of implementing a narrow bezel and increasing the flexibility of display panel design by relieving a limitation on the bezel size of the display panel while preventing or suppressing damage to the GIP circuit through an outer structure of the display panel that is robust to electrostatic discharge, without expanding the bezel region.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these and other advantages and in accordance with the purpose of the present disclosure, as embodied and broadly described herein, a light emitting display apparatus according to one or more embodiments of the present disclosure may include a substrate including a display area in which a plurality of subpixels, each comprising a pixel electrode, an emission layer, and a common electrode, are disposed, and a non-display area surrounding the display area, a gate driving circuit disposed in the non-display area and configured to drive a plurality of gate lines disposed in the display area, a first low-potential voltage line disposed in the non-display area and surrounding the display area, and a second low-potential voltage line disposed between the first low-potential voltage line and the gate driving circuit in the non-display area, the first low-potential voltage line and the second low-potential voltage line may be electrically connected to the common electrode.

According to one or more embodiments of the present disclosure, a light emitting display apparatus may be provided that is capable of improving the reliability of the display panel by blocking the inflow of electrostatic discharge occurring during the cutting process or the scribing process of the display panel or by increasing the inflow path, thereby reducing a malfunction in driving the GIP circuit of the display panel.

According to one or more embodiments of the present disclosure, a light emitting display apparatus may be provided that is capable of implementing a narrow bezel and increasing the flexibility of display panel design by relieving a limitation on the bezel size of the display panel while preventing or suppressing damage to the GIP circuit through an outer structure of the display panel that is robust to electrostatic discharge, without expanding the bezel region.

The light emitting display apparatus according to one or more embodiments of the present disclosure may reduce the bezel region while preventing or suppressing damage to the GIP circuit through an outer structure of the display panel that is robust to electrostatic discharge and configured to block the inflow of electrostatic discharge or increase the inflow path during a cutting process or a scribing process of the display panel. Accordingly, a narrow bezel may be implemented to improve the aesthetics and visibility of the display device, and the defect rate caused by electrostatic discharge generated during the manufacturing process may be reduced, thereby improving production yield and reliability. As a result, emissions of greenhouse gases associated with the manufacturing process may be reduced, thereby contributing to the implementation of Environmental, Social, and Governance (ESG) principles.

The effects of the present disclosure are not limited to the aforesaid, but other effects not described herein will be clearly understood by those skilled in the art from the following descriptions.

The details of the present disclosure described in technical problem, technical solution, and advantageous effects do not necessarily specify features of claims. Thus, the scope of claims is not limited by the details described in detailed description of the disclosure.

### BRIEF DESCRIPTION OF THE DRAWINGS

The accompanying drawings, which are included to provide a further understanding of the present disclosure, are incorporated in and constitute a part of this disclosure, illustrate aspects and example embodiments of the disclosure, and together with the description serve to explain various principles and examples of the disclosure.

FIG. 1 illustrates a schematic configuration of a display apparatus according to an example embodiment of the present disclosure.

FIG. 2 illustrates a system of a display apparatus according to an example embodiment of the present disclosure.

FIG. 3 illustrates a mother substrate on which a plurality of display panels are formed according to an example embodiment of the present disclosure.

FIG. 4 is a cross-sectional view taken along line I-I′ in FIG. 3 according to an example embodiment of the present disclosure.

FIGS. 5 and 6 illustrate a scribing process for separating a display panel according to an example embodiment of the present disclosure.

FIG. 7 illustrates a display panel according to an example embodiment of the present disclosure.

FIG. 8 illustrates region A shown in FIG. 7 according to an example embodiment of the present disclosure.

FIG. 9 illustrates region B shown in FIG. 8 according to an example embodiment of the present disclosure.

FIG. 10 is a cross-sectional view taken along line II-II′ in FIG. 9 according to an example embodiment of the present disclosure.

FIG. 11 illustrates a display panel according to another example embodiment of the present disclosure.

FIG. 12 illustrates a display panel according to another example embodiment of the present disclosure.

FIG. 13 illustrates a display panel according to another example embodiment of the present disclosure.

Throughout the drawings and the detailed description, unless otherwise described, the same drawing reference numerals should be understood to refer to the same elements, features, and/or structures. The sizes, lengths, and thicknesses of layers, regions and elements, and depiction of thereof may be exaggerated for clarity, illustration, and/or convenience.

### DETAILED DESCRIPTION

Advantages and features of the present disclosure, and implementation methods thereof, are clarified through various example embodiments described with reference to the accompanying drawings. The present disclosure may, however, be embodied in different forms and should not be construed as limited to the embodiments set forth herein. Rather, these embodiments are examples and are provided so that this disclosure may be more thorough and complete, to assist those skilled in the art to understand the inventive concepts without limiting the protected scope of the present disclosure.

Shapes (e.g., sizes, lengths, widths, heights, thicknesses, locations, radii, diameters, and areas), sizes, ratios, angles, numbers, and the like disclosed herein, including those illustrated in the drawings, are merely examples. Thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

Where the term “comprise,” “have,” “include,” “contain,” “constitute,” “made of,” “formed of,” or the like is used with respect to one or more elements, one or more other elements may be added unless a more limiting term, such as “only” or the like, is used. The terms used in the present disclosure are merely used to describe example embodiments and are not intended to limit the scope of the present disclosure. The terms of a singular form may include plural forms, and vice versa, unless the context clearly indicates otherwise.

In construing an element, the element is to be construed as including an error region although there is no explicit description thereof.

In describing a positional relationship, for example, where the positional order is described as “on,” “above,” “below,” “beneath,” and “next,” the case of no contact therebetween may be included, unless a more limiting term like “just” or “direct” is used.

If a first element is described as being positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, where the temporal order is described as “after,” “subsequent,” “next,” and “before,” a case which is not continuous may be included, unless a more limiting term like “just” or “direct” is used.

It should be understood that, although the terms “first,” “second,” etc., may be used herein to describe various elements, these elements should not be limited by these terms. These terms are only used to refer to one element separately from another. For example, a first element could be termed a second element, and, similarly, a second element could be termed a first element.

In describing elements of the present disclosure, the terms “first,” “second,” “A,” “B,” “(a),” “(b),” or the like may be used. These terms are intended to identify the corresponding element(s) separately from the other element(s), and are not used to define the essence, basis, order, or number of the elements.

For the expression that an element is “connected,” “coupled,” “attached,” or “adhered” to another element, or for similar expressions, the element may not only be directly connected, coupled, attached, or adhered to another element, but may also be indirectly connected, coupled, attached, or adhered to another element with one or more intervening elements disposed or interposed between the elements, unless otherwise specified.

For the expression that an element “contacts” or “overlaps” another element, or for similar expressions, the element may not only directly contact or overlap another element, but may also indirectly contact or overlap another element with one or more intervening elements disposed or interposed between the elements, unless otherwise specified.

The term “at least one” should be understood as including any and all combinations of one or more of the associated listed items. For example, “at least one among a first element, a second element, and a third element” may include all combinations of two or more elements selected from the first, second, and third elements, as well as each of the first, second and third elements individually.

Features of various embodiments of the present disclosure may be partially or entirely coupled to or combined with each other, may be technically associated with each other, and may be variously inter-operated, linked, or driven together. The embodiments of the present disclosure may be implemented or carried out independently of each other, or may be implemented or carried out together in a co-dependent or associated relationship. In one or more aspects, the components of each apparatus according to various embodiments of the present disclosure may operatively be coupled and configured.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness. Thus, embodiments of the present disclosure are not limited to a particular scale, dimension, size, and/or thickness illustrated in the drawings.

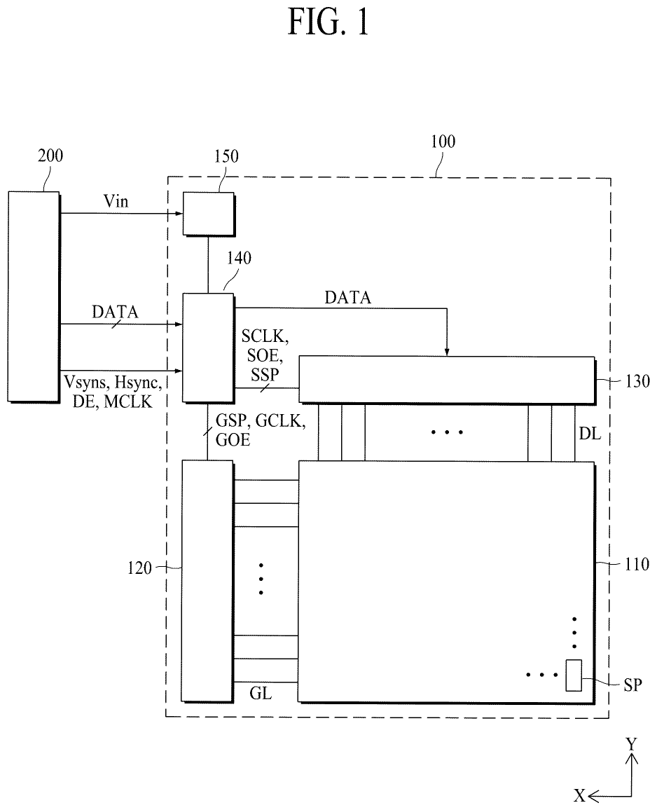

FIG. 1 illustrates a schematic configuration of a display apparatus according to an example embodiment of the present disclosure.

As shown in FIG. 1, a display apparatus 100 according to an example embodiment of the present disclosure may include a display panel 110 in which a plurality of subpixels SP are arranged in a matrix form and a plurality of gate lines GL and data lines DL are connected, a gate driving circuit 120 configured to drive the plurality of gate lines GL, a data driving circuit 130 configured to supply data voltages through the plurality of data lines DL, a timing controller 140 configured to control the gate driving circuit 120 and the data driving circuit 130, and a power management IC (PMIC) 150.

The display panel 110 may display images based on the scan signals supplied from the gate driving circuit 120 through the plurality of gate lines GL and the data voltages supplied from the data driving circuit 130 through the plurality of data lines DL.

The display panel 110 may include a plurality of pixels arranged in a matrix form, and each pixel may include subpixels SP of different colors. For example, the plurality of subpixels SP may include a red subpixel, a green subpixel, a blue subpixel, and a white subpixel. Each subpixel SP may be defined by the plurality of data lines DL and the plurality of gate lines GL.

Each pixel may include four subpixels SP of red, green, blue, and white. When the resolution of the display panel 110 is configured as 2,160×3,840, a total of 15,360 data lines DL may be included by providing 3,840 data lines DL for each of the four subpixels SP and 2,160 gate lines GL. Each subpixel SP may be disposed at an intersection of the gate lines GL and the data lines DL.

The gate driving circuit 120 may be controlled by the timing controller 140 and may sequentially output scan signals to the plurality of gate lines GL to control the driving timing of the plurality of subpixels SP.

In a display apparatus 100 with a resolution of 2,160×3,840, when scan signals are sequentially output from the first gate line to the 2,160th gate line, this is referred to as a 2,160-phase driving. Alternatively, sequentially outputting scan signals from the first gate line to the fourth gate line, followed by sequentially outputting scan signals from the fifth gate line to the eighth gate line, is referred to as a 4-phase driving. For example, sequentially outputting scan signals for every N gate lines GL is referred to as N-phase driving.

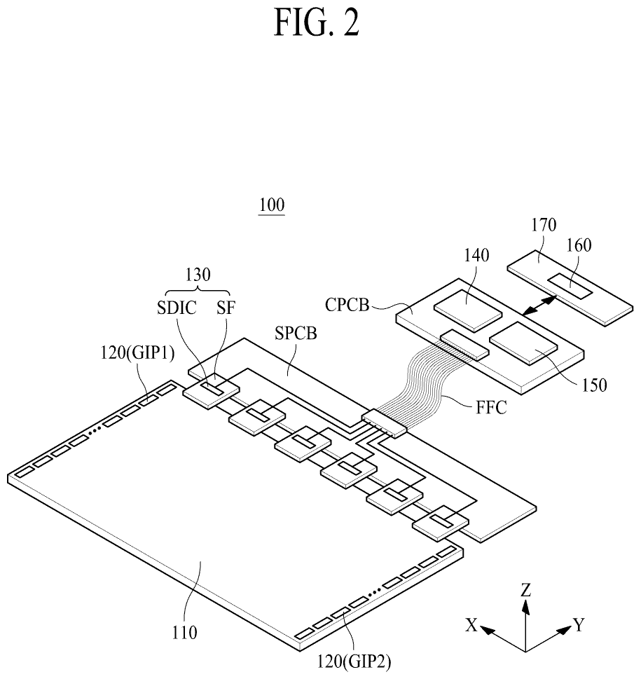

The gate driving circuit 120 may include one or more gate driving circuits GIP1 and GIP2 (see FIG. 2). For example, one or more gate driving circuits GIP1 and GIP2 may be located at both sides of the display panel 110, or located only at one side of the display panel 110 depending on the driving method, but the embodiments of the present disclosure are not limited thereto. One or more gate driving circuits GIP1 and GIP2 may be implemented in a Gate In Panel (GIP) form and embedded in a bezel area of the display panel 110.

The data driving circuit 130 may receive image data DATA from the timing controller 140 and convert the received image data DATA into an analog data voltage. The data driving circuit 130 may output the data voltage to each of the data lines DL in synchrony with the timing when a scan signal is applied through the gate lines GL, so that each subpixel SP connected to the data lines DL may display a light emission signal corresponding to the brightness of the data voltage.

The data driving circuit 130 may include one or more source driving integrated circuits SDICs (see FIG. 2). The source driving integrated circuits SDIC may be connected to the bonding pads of the display panel 110 by a TAB (Tape Automated Bonding) method or a COF (Chip On Film) method, or may be directly mounted on the display panel 110.

According to an embodiment of the present disclosure, each source driving integrated circuit SDIC may be integrated and disposed on the display panel 110. Each source driving integrated circuit SDIC may be implemented in the COF (Chip On Film) method and mounted on a circuit film, electrically connecting the data lines DL of the display panel 110 through the circuit film.

The timing controller 140 may supply various control signals to the gate driving circuit 120 and the data driving circuit 130, and may control the operations of the gate driving circuit 120 and the data driving circuit 130. For example, the timing controller 140 may control the gate driving circuit 120 to output scan signals according to the timing implemented for each frame, and may transmit the digital image data DATA received from an external source to the data driving circuit 130.

The timing controller 140 may receive various timing signals, including image data DATA, a vertical synchronization signal Vsync, a horizontal synchronization signal Hsync, a data enable signal DE, and a main clock MCLK, from an external host system 200. For example, the host system 200 may be at least one of a television TV system, a set-top box, a navigation system, a personal computer PC, a home theater system, a mobile device, and a wearable device, but embodiments of the present disclosure are not limited thereto.

The timing controller 140 may generate control signals using various timing signals received from the host system 200, and may transmit these control signals to the gate driving circuit 120 and the data driving circuit 130.

The timing controller 140 may output various gate control signals, including a gate start pulse GSP, a gate clock GCLK, and a gate output enable signal GOE, to control the gate driving circuit 120. For example, the gate start pulse GSP may control the timing at which one or more gate driving circuits GIP1 and GIP2 constituting the gate driving circuit 120 begin operation. The gate clock GCLK is a clock signal input to one or more gate driving circuits GIP1 and GIP2 in common and may control the shift timing of the scan signal. The gate output enable signal GOE may control the output timing of one or more gate driving circuits GIP1 and GIP2.

The timing controller 140 may output various data control signals, including a source start pulse SSP, a source sampling clock SCLK, and a source output enable signal SOE, to control the data driving circuit 130. For example, the source start pulse SSP may control the timing at which one or more source driving integrated circuits SDIC constituting the data driving circuit 130 begin data sampling. The source sampling clock SCLK may be a clock signal that controls the timing of data sampling in the source driving integrated circuit SDIC. The source output enable signal SOE may control the output timing of the data driving circuit 130.

The display apparatus 100 according to an example embodiment of the present disclosure may include a power management IC 150 configured to supply various voltages or currents to the display panel 110, the gate driving circuit 120, the data driving circuit 130, or to control various voltages or currents to be supplied.

The power management IC 150 may generate power for driving the display panel 110, the gate driving circuit 120, and the data driving circuit 130 by adjusting a direct current input voltage Vin supplied from the host system 200.

FIG. 2 illustrates a system of a display apparatus according to an example embodiment of the present disclosure.

In the following, the X-axis represents the direction parallel to the scan lines (or gate lines), the Y-axis represents the direction parallel to the data lines, and the Z-axis represents the height direction of the display apparatus.

As shown in FIG. 2, the display apparatus 100 according to an example embodiment of the present disclosure may include a source driving integrated circuit SDIC implemented in a COF (Chip On Film) method, and a gate driving circuit 120 implemented in a GIP (Gate In Panel) form.

The gate driving circuit 120 may be implemented in the form of GIP, and a plurality of gate driving circuits GIP1 and GIP2 included in the gate driving circuit 120 may be directly formed in a non-display area (or bezel area) of the display panel 110. For example, the plurality of gate driving circuits GIP1 and GIP2 may receive various signals (such as clock signals, gate high signals, gate low signals, etc.) for generating scan signals through gate driving-related signal lines disposed in the non-display area. For example, the plurality of gate driving circuits GIP1 and GIP2 may be disposed along a second direction (or Y-axis direction) that intersects with a first direction (or X-axis direction) at each of the non-display areas located on both sides of the display panel 110 in the first direction (or X-axis direction).

The data driving circuit 130 may be implemented in the form of the COF, and the plurality of source driving integrated circuits SDIC included in the data driving circuit 130 may be mounted on a source film SF. One side of the source film SF may be electrically connected to the display panel 110. COF wiring for electrically connecting the source driving integrated circuits SDIC to the display panel 110 may be disposed on top of the source film SF. For example, a plurality of source driving integrated circuits SDIC may be disposed in a non-display area located on one side (or upper side) of the display panel 110 in the second direction (or Y-axis direction), and may be disposed at regular intervals along the first direction (or X-axis direction).

The display apparatus 100 may include at least one source printed circuit board SPCB for circuit connections between a plurality of source driving integrated circuits SDIC and other devices, and a control printed circuit board CPCB for mounting control components and various electrical devices.

The at least one source printed circuit board SPCB may be connected to the other side of the source film SF where the source driving integrated circuits SDIC are mounted. For example, the source film SF, on which the source driving integrated circuits SDIC are mounted, may have one side electrically connected to the display panel 110, and the other side may be electrically connected to the source printed circuit board SPCB.

The control printed circuit board CPCB may mount the timing controller 140 and the power management IC (PMIC) 150. The timing controller 140 may control the operation of the data driving circuit 130 and the gate driving circuit 120. The power management IC 150 may supply or control the supply of driving voltages or currents for the display panel 110, data driving circuit 130, and gate driving circuit 120.

The at least one source printed circuit board SPCB and the control printed circuit board CPCB may be electrically connected through at least one connection member, which may be a flexible flat cable FFC. For example, the connection member may also be a flexible printed circuit (FPC). For example, the at least one source printed circuit board SPCB and the control printed circuit board CPCB may be integrated into a single printed circuit board, but the embodiments of the present disclosure are not limited to this configuration.

The display apparatus 100 may further include a set board 170 electrically connected to the control printed circuit board CPCB. For example, the set board 170 may be referred to as a power board. The set board 170 may include a main power management circuit (M-PMC) 160 that manages the overall power of the display apparatus 100. The main power management circuit (M-PMC) 160 may be linked to the power management IC (PMIC) 150.

The driving voltage generated by the set board 170 may be transmitted to the power management IC (PMIC) 150 in the control printed circuit board CPCB. The power management IC (PMIC) 150 may transmit the driving voltage for the operation or characteristic sensing of the display apparatus 100 to the source printed circuit board SPCB via the flexible flat cable FFC. The driving voltage transmitted to the source printed circuit board SPCB may be supplied to the gate driving circuit 120, the data driving circuit 130, and the display panel 110. For example, the power management IC (PMIC) 150 may supply the driving voltage for the emission or sensing of subpixels SP in the display panel 110 via the source driving integrated circuits SDIC.

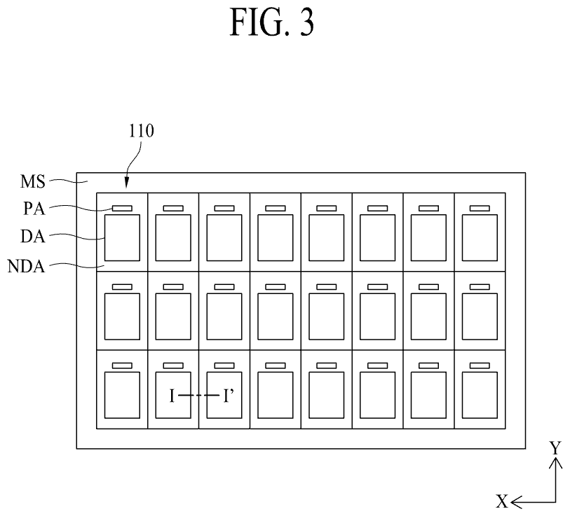

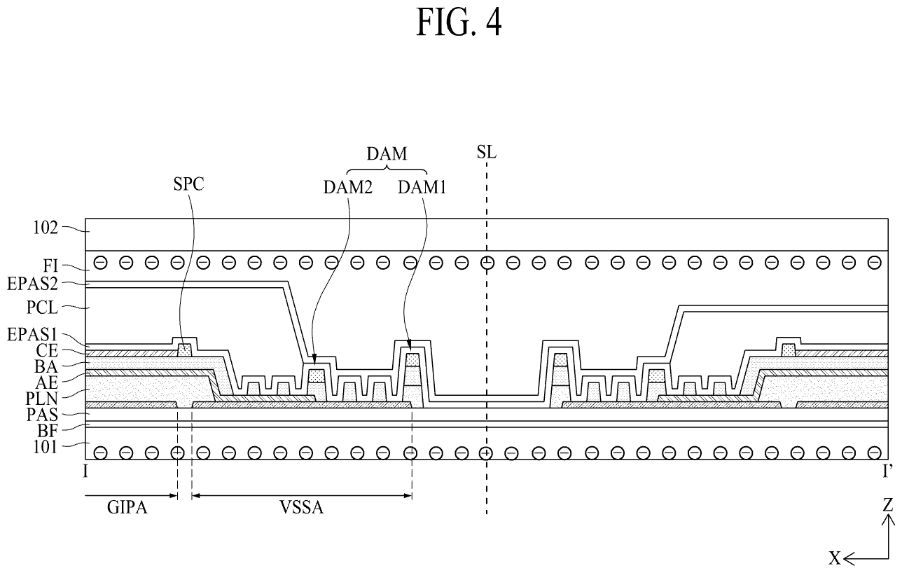

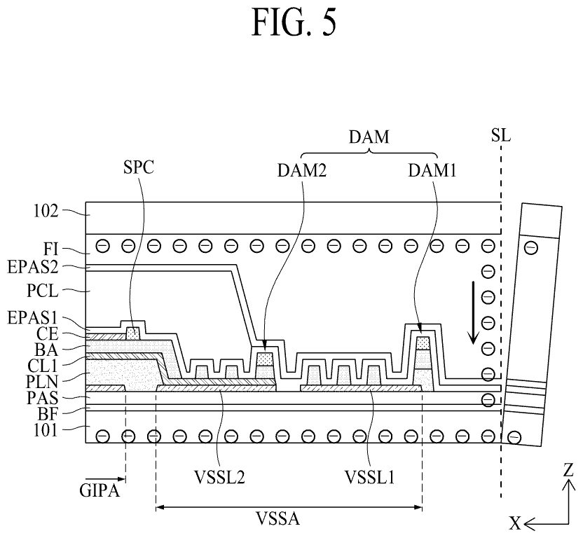

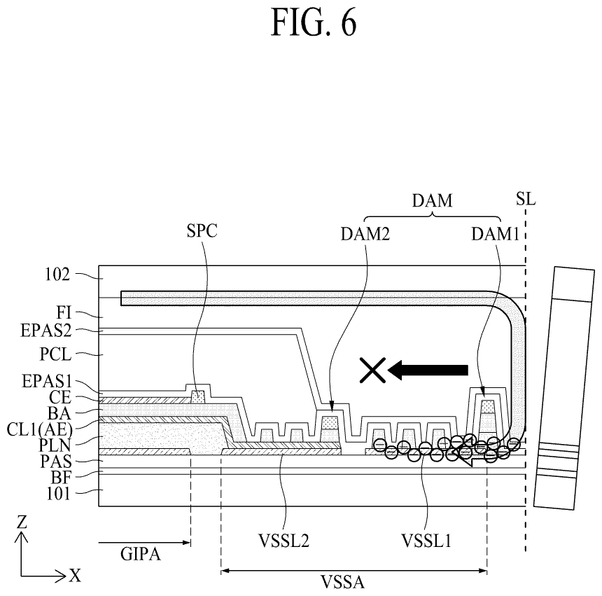

FIG. 3 illustrates a mother substrate on which a plurality of display panels are formed according to an example embodiment of the present disclosure. FIG. 4 is a cross-sectional view taken along line I-I′ in FIG. 3 according to an example embodiment of the present disclosure. FIGS. 5 and 6 illustrate a scribing process for separating a display panel according to an example embodiment of the present disclosure.

As shown in FIGS. 3 to 6, a mother substrate MS according to an example embodiment of the present disclosure may be a substrate for manufacturing a plurality of display panels 110 for process convenience. For example, the plurality of display panels 110 may be simultaneously formed on the mother substrate MS and may be individually separated through a scribing process. The separated display panels 110 may function as a light emitting display apparatus 100. Each display panel 110 may include a display area DA, a non-display area NDA, and a pad area PA. For example, the scribing process may be a cutting process using a laser or a cutting process applying a direct physical force to the substrate using a mechanical tool such as a cutter.

The scribing process may be performed along a predetermined scribing line SL between adjacent display panels 110 on the mother substrate MS. Each separated display panel 110 may receive signals via a separate connection member connected to its pad area PA. For example, the connection member may be implemented in a COF (Chip On Film) method, but embodiments of the present disclosure are not limited thereto.

As shown in FIG. 4, each adjacent display panel 110 on the mother substrate MS may include a first substrate 101 (or array substrate) on which a plurality of subpixels SP are disposed and a second substrate 102 (or counter substrate) facing the first substrate 101. For example, the display panel 110 may be implemented in a top emission type or a bottom emission type depending on the structure of the plurality of subpixels SP. For example, when the display panel 110 is implemented in the top emission type, the second substrate 102 may be a color filter substrate in which a color filter is disposed. Alternatively, when implemented in the bottom emission type, the second substrate 102 may be a protective substrate for protecting the plurality of subpixels SP disposed on the first substrate 101, but embodiments of the present disclosure are not limited thereto.

The first substrate 101 and the second substrate 102 may be bonded to each other by a connection member FI (or adhesive member). For example, each display panel 110 adjacent on the mother substrate MS may be separated from each other by cutting along the scribing line SL, and the scribing line SL may become the edge of each separated display panel 110.

A buffer layer BF may be disposed on the first substrate 101. At least one thin film transistor may be disposed on the buffer layer BF, and one or more insulating layers covering the at least one thin film transistor may be disposed on the buffer layer BF. For example, the one or more insulating layers may include a passivation layer PAS. A planarization layer PLN may be disposed on the passivation layer PAS, and a low-potential voltage line may be disposed between the passivation layer PAS and the planarization layer PLN.

In the display area DA, a pixel electrode AE of each of the plurality of subpixels SP may be disposed on the planarization layer PLN, and a bank portion BA covering the edge of the pixel electrode AE may be disposed. An emission layer may be disposed on the pixel electrode AE, and a common electrode CE may be disposed on the emission layer. The pixel electrode AE may be patterned for each subpixel SP. The common electrode CE may be a common layer commonly formed for the plurality of subpixels SP. The common electrode CE may be stacked with the pixel electrode AE and the emission layer to constitute a light emitting device of the plurality of subpixels SP, and may also be disposed on the bank portion BA.

An encapsulation layer may be further disposed on the first substrate 101. The encapsulation layer may include a first inorganic layer EPAS1, an organic layer PCL, and a second inorganic layer EPAS2. The first inorganic layer EPAS1 may be disposed on the common electrode CE of the plurality of subpixels SP, the organic layer PCL may be disposed on the first inorganic layer EPAS1, and the second inorganic layer EPAS2 may be disposed on the organic layer PCL.

The display panel 110 may include the display area DA in which the plurality of subpixels SP are disposed and the non-display area NDA surrounding the display area DA. In the non-display area NDA of the first substrate 101, a gate driving circuit 120 including at least one signal line and at least one thin film transistor may be disposed.

The non-display area NDA of the display panel 110 according to one embodiment of the present disclosure may include a low-potential voltage line area VSSA in which a first low-potential voltage line VSSL1 and a second low-potential voltage line VSSL2 for supplying a low potential voltage to the common electrode CE of the plurality of subpixels SP are disposed, and a gate driving circuit area GIPA for driving gate lines GL connected to the plurality of subpixels SP.

The first low-potential voltage line VSSL1 may have a line width greater than that of the second low-potential voltage line VSSL2. The first low-potential voltage line VSSL1 and the second low-potential voltage line VSSL2 may be spaced apart from each other.

The first low-potential voltage line VSSL1 and the second low-potential voltage line VSSL2 may be formed of the same material in the same layer on the first substrate 101. For example, the first and second low-potential voltage lines VSSL1 and VSSL2 may be disposed on the passivation layer PAS of the first substrate 101.

The first low-potential voltage line VSSL1 may be disposed adjacent to the edge of the first substrate 101, and the second low-potential voltage line VSSL2 may be disposed adjacent to the gate driving circuit area GIPA.

The first low-potential voltage line VSSL1 may be spaced apart from the second low-potential voltage line VSSL2 by a predetermined distance, thereby blocking the inflow of electrostatic charges into the second low-potential voltage line VSSL2 or increasing the inflow path.

The non-display area NDA may further include a dam portion DAM. The dam portion DAM may be configured to surround an inner side of the edge of the first substrate 101 in the non-display area NDA. The dam portion DAM may be disposed to overlap the low-potential voltage line area VSSA in the non-display area NDA. The dam portion DAM may prevent or suppress the organic layer PCL of the encapsulation layer from overflowing outward during the encapsulation process. The dam portion DAM may be disposed to surround the display area DA and may have a closed loop shape in plan view.

The dam portion DAM may be configured in a stacked form including at least one of the planarization layer PLN, the bank portion BA, and a spacer SPC. For example, the dam portion DAM may include a plurality of dams DAM1 and DAM2. The plurality of dams DAM1 and DAM2 may include a first dam DAM1 and a second dam DAM2. The first dam DAM1 may include the planarization layer PLN, the bank portion BA, and the spacer SPC, and the second dam DAM2 may include the bank portion BA and the spacer SPC, but embodiments of the present disclosure are not limited thereto. For example, the dam portion DAM may include an auxiliary dam formed of the bank portion BA.

According to an example embodiment of the present disclosure, the first low-potential voltage line VSSL1 may overlap the second inorganic layer EPAS2 of the encapsulation layer. Furthermore, the first low-potential voltage line VSSL1 may overlap the first dam DAM1. For example, the first dam DAM1 may include the planarization layer PLN, the bank portion BA, and the spacer SPC, but embodiments of the present disclosure are not limited thereto.

The second low-potential voltage line VSSL2 may be electrically connected to a first connection line CL1 formed of the same material as the pixel electrode AE disposed in the display area DA. The second low-potential voltage line VSSL2 may be electrically connected to the common electrode CE extended from the display area DA through the first connection line CL1. The second low-potential voltage line VSSL2 may overlap the first inorganic layer EPAS1, the organic layer PCL, and the second inorganic layer EPAS2 of the encapsulation layer. Furthermore, the second low-potential voltage line VSSL2 may overlap the second dam DAM2. For example, the second dam DAM2 may include the bank portion BA and the spacer SPC, but embodiments of the present disclosure are not limited thereto.

As shown in FIG. 4, the scribing process for separating the display panel according to an example embodiment of the present disclosure may include a scribing preparation process for individually separating the plurality of display panels 110 from the mother substrate MS. In this case, electric charges may be generated on the first substrate 101 and the second substrate 102. For example, the electric charges may be formed on the surface of the first substrate 101 and the lower surface of the second substrate 102.

As shown in FIG. 5, during the scribing process, a laser may be irradiated to the top of the second substrate 102, and cutting may proceed along the scribing line SL, so that the charges formed in the second substrate 102 may move to the first substrate 101 along the cutting cross-section. In this process, charges may accumulate on the upper surface of the first substrate 101, and charges may be stored in the low-potential voltage line area VSSA on the first substrate 101 adjacent to the scribing line SL. The charges accumulated in the low-potential voltage line area VSSA may be discharged through the first connection line CL1 connected to the low-potential voltage line area VSSA. During this discharge process, electrostatic discharge (ESD) having a high instantaneous voltage may occur, and electrical stress may be applied to the gate driving circuit area GIPA overlapped with the first connection line CL1.

As shown in FIG. 6, after the scribing process is completed, the display panel 110 according to an example embodiment of the present disclosure may be separated from other display panels 110 outside the scribing line SL. In this process, charges may accumulate on the upper surface of the first substrate 101, and charges may be stored in the first low-potential voltage line VSSL1 on the first substrate 101 adjacent to the scribing line SL. The charges accumulated in the first low-potential voltage line VSSL1 may be discharged, causing electrostatic discharge.

According to an example embodiment of the present disclosure, the first low-potential voltage line VSSL1 may be spaced apart from the second low-potential voltage line VSSL2, thereby blocking the inflow of electrostatic discharge generated from the first low-potential voltage line VSSL1 into the second low-potential voltage line VSSL2 or increasing the inflow path. For example, the electrostatic charge generated in the first low-potential voltage line VSSL1 may naturally dissipate without flowing into the second low-potential voltage line VSSL2 or have its electrical impact minimized or reduced due to the increased inflow path.

The light emitting display apparatus according to an example embodiment of the present disclosure may include first and second low-potential voltage lines VSSL1 and VSSL2 that block the inflow of electrostatic discharge or increase the inflow path during the scribing process, thereby preventing or suppressing damage to the gate driving circuit GIP1 and GIP2 and reducing the bezel area. Accordingly, the light emitting display apparatus may reduce gate driving circuit GIP1 and GIP2 malfunction in the display panel 110, enhance panel reliability, and provide a narrow bezel light emitting display apparatus.

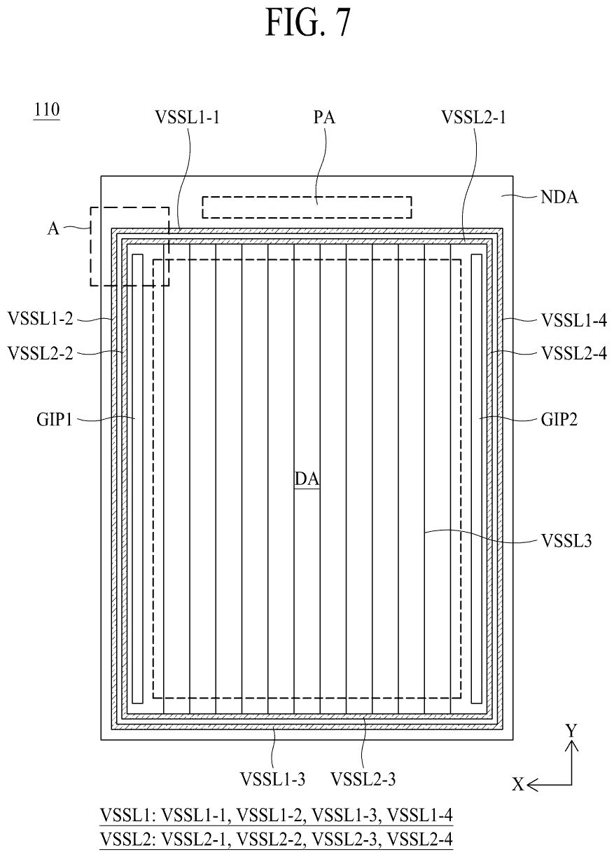

FIG. 7 illustrates a display panel according to an example embodiment of the present disclosure.

As shown in FIG. 7, a display panel 110 according to an example embodiment of the present disclosure may include a display area DA in which a plurality of subpixels SP are disposed, and a non-display area NDA surrounding the display area DA. The display area DA may be a region in which images are displayed by the plurality of subpixels SP, and the non-display area NDA may be a region in which images are not displayed.

The non-display area NDA of the display panel 110 may include a pad area PA in which pads for receiving external signals are disposed, and a plurality of gate driving circuits GIP1 and GIP2. The plurality of gate driving circuits GIP1 and GIP2 may drive a plurality of gate lines GL (see FIG. 1) extending in a first direction (or X-axis direction) in the display area DA. The plurality of gate driving circuits GIP1 and GIP2 may include a first gate driving circuit GIP1 disposed on the left side in the first direction and a second gate driving circuit GIP2 disposed on the right side in the first direction. The pad area PA may be disposed in the non-display area NDA adjacent to a first edge (or upper edge) of the display panel 110. The non-display area NDA may include a non-pad area that faces the pad area PA across the display area DA. For example, the non-pad area may be a region in which pads are not disposed.

The display panel 110 according to an example embodiment of the present disclosure may include a first low-potential voltage line VSSL1 and a second low-potential voltage line VSSL2. The first low-potential voltage line VSSL1 may be disposed in the non-display area NDA and may be configured to surround the display area DA. The second low-potential voltage line VSSL2 may be disposed between the first low-potential voltage line VSSL1 and the gate driving circuits GIP1 and GIP2 in the non-display area NDA. The first low-potential voltage line VSSL1 and the second low-potential voltage line VSSL2 may be electrically connected to a common electrode CE of the plurality of subpixels SP.

The first low-potential voltage line VSSL1 may include a first portion VSSL1-1 disposed adjacent to a first edge (or upper edge) of the display panel 110 and extending in a first direction (or X-axis direction), a second portion VSSL1-2 disposed adjacent to a second edge (or left edge) of the display panel 110 perpendicular to the first edge and extending in a second direction (or Y-axis direction) intersecting the first direction, a third portion VSSL1-3 disposed adjacent to a third edge (or lower edge) of the display panel 110 opposite to the first edge and extending in the first direction; and a fourth portion VSSL1-4 disposed adjacent to a fourth edge (or right edge) of the display panel 110 opposite to the second edge and extending in the second direction. For example, the first portion VSSL1-1, the second portion VSSL1-2, the third portion VSSL1-3, and the fourth portion VSSL1-4 of the first low-potential voltage line VSSL1 may be connected to form a closed loop shape.

The first portion VSSL1-1 of the first low-potential voltage line VSSL1 may be disposed between the pad area PA and the display area DA. The first portion VSSL1-1 and the third portion VSSL1-3 of the first low-potential voltage line VSSL1 may have the same line width. The second portion VSSL1-2 and the fourth portion VSSL1-4 of the first low-potential voltage line VSSL1 may have the same line width. Also, the first portion VSSL1-1 and the third portion VSSL1-3 of the first low-potential voltage line VSSL1 may have a line width equal to or greater than that of the second portion VSSL1-2 and the fourth portion VSSL1-4. For example, the first and third portions VSSL1-1 and VSSL1-3 may be configured to have a greater line width than the second and fourth portions VSSL1-2 and VSSL1-4.

A corner where the first portion VSSL1-1 and the second portion VSSL1-2 of the first low-potential voltage line VSSL1 meet, a corner where the first portion VSSL1-1 and the fourth portion VSSL1-4 meet, a corner where the third portion VSSL1-3 and the second portion VSSL1-2 meet, and a corner where the third portion VSSL1-3 and the fourth portion VSSL1-4 meet may be configured to have a rounded shape.

The second low-potential voltage line VSSL2 may extend in the second direction (or Y-axis direction) between the first low-potential voltage line VSSL1 and the gate driving circuits GIP1 and GIP2. For example, the second low-potential voltage line VSSL2 may be disposed between the second portion VSSL1-2 of the first low-potential voltage line VSSL1 and the first gate driving circuit GIP1, and between the fourth portion VSSL1-4 of the first low-potential voltage line VSSL1 and the second gate driving circuit GIP2. For example, the second low-potential voltage line VSSL2 may be electrically connected between the first portion VSSL1-1 and the third portion VSSL1-3 of the first low-potential voltage line VSSL1. For example, the second low-potential voltage line VSSL2 may be configured to have a smaller line width than the first low-potential voltage line VSSL1.

The second low-potential voltage line VSSL2 may be configured to surround the display area DA between the first low-potential voltage line VSSL1 and the display area DA. The second low-potential voltage line VSSL2 may include a first portion VSSL2-1 disposed between the first portion VSSL1-1 of the first low-potential voltage line VSSL1 and the display area DA and parallel to the first portion VSSL1-1, a second portion VSSL2-2 disposed between the second portion VSSL1-2 of the first low-potential voltage line VSSL1 and the first gate driving circuit GIP1 and parallel to the second portion VSSL1-2, a third portion VSSL2-3 disposed between the third portion VSSL1-3 of the first low-potential voltage line VSSL1 and the display area DA and parallel to the third portion VSSL1-3, and a fourth portion VSSL2-4 disposed between the fourth portion VSSL1-4 of the first low-potential voltage line VSSL1 and the second gate driving circuit GIP2 and parallel to the fourth portion VSSL1-4. For example, the first to fourth portions VSSL2-1 to VSSL2-4 of the second low-potential voltage line VSSL2 may be connected to form a closed loop shape.

The display panel 110 according to an example embodiment of the present disclosure may further include a plurality of third low-potential voltage lines VSSL3 disposed in the display area DA and extending in the second direction (or Y-axis direction). The plurality of third low-potential voltage lines VSSL3 may be electrically connected to either the first low-potential voltage line VSSL1 or the second low-potential voltage line VSSL2. For example, the plurality of third low-potential voltage lines VSSL3 may be electrically connected to the second low-potential voltage line VSSL2.

The plurality of third low-potential voltage lines VSSL3 may be electrically connected between the first portion VSSL1-1 and the third portion VSSL1-3 of the first low-potential voltage line VSSL1, or between the first portion VSSL2-1 and the third portion VSSL2-3 of the second low-potential voltage line VSSL2. For example, the plurality of third low-potential voltage lines VSSL3 may be electrically connected between the first portion VSSL2-1 and the third portion VSSL2-3 of the second low-potential voltage line VSSL2.

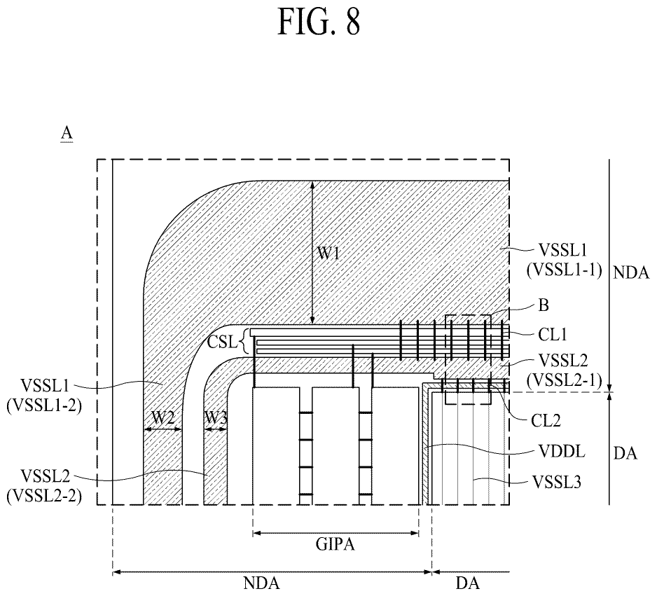

FIG. 8 illustrates region A shown in FIG. 7 according an example embodiment of the present disclosure.

As shown in FIG. 8, the non-display area NDA of the display panel 110 according to an example embodiment of the present disclosure may include a first low-potential voltage line VSSL1, a second low-potential voltage line VSSL2, a first connection line CL1, a high-potential voltage line VDDL, a gate driving circuit area GIPA, and at least one control signal line CSL. Also, the display area DA of the display panel 110 may include a plurality of third low-potential voltage lines VSSL3 and a second connection line CL2.

The first low-potential voltage line VSSL1 and the second low-potential voltage line VSSL2 may be spaced apart from each other. The first connection line CL1 may electrically connect the first low-potential voltage line VSSL1 and the second low-potential voltage line VSSL2. At least one control signal line CSL may be disposed between the first low-potential voltage line VSSL1 and the second low-potential voltage line VSSL2. For example, the at least one control signal line CSL may be electrically connected to the gate control signal area GIPA.

The first low-potential voltage line VSSL1 may include a first portion VSSL1-1 extending in a first direction (or X-axis direction) and a second portion VSSL1-2 extending in a second direction (or Y-axis direction). The first portion VSSL1-1 and the second portion VSSL1-2 of the first low-potential voltage line VSSL1 may have different line widths. For example, the first portion VSSL1-1 of the first low-potential voltage line VSSL1 may have a first line width W1, and the second portion VSSL1-2 of the first low-potential voltage line VSSL1 may have a second line width W2 smaller than the first line width W1. A corner where the first portion VSSL1-1 and the second portion VSSL1-2 of the first low-potential voltage line VSSL1 meet may be configured to have a rounded shape.

The second low-potential voltage line VSSL2 may include a first portion VSSL2-1 extending in the first direction (or X-axis direction) and a second portion VSSL2-2 extending in the second direction (or Y-axis direction). For example, the second low-potential voltage line VSSL2 may have a different line width from that of the first low-potential voltage line VSSL1. For example, the second low-potential voltage line VSSL2 may have a third line width W3. The third line width W3 of the second low-potential voltage line VSSL2 may be smaller than each of the first line width W1 and the second line width W2 of the first low-potential voltage line VSSL1.

The high-potential voltage line VDDL may supply a driving voltage to the plurality of subpixels SP. The high-potential voltage line VDDL may be configured to surround the display area DA. The high-potential voltage line VDDL may be disposed between the second low-potential voltage line VSSL2 and the display area DA.

The plurality of third low-potential voltage lines VSSL3 may be disposed in the display area DA. The second connection line CL2 may electrically connect the second low-potential voltage line VSSL2 and the plurality of third low-potential voltage lines VSSL3. As stated previously, the plurality of third low-potential voltage lines VSSL3 may be also electrically connected to the first low-potential voltage line VSSL1, and in this case, the second connection line CL2 may electrically connect the first low-potential voltage line VSSL1 and the plurality of third low-potential voltage lines VSSL3.

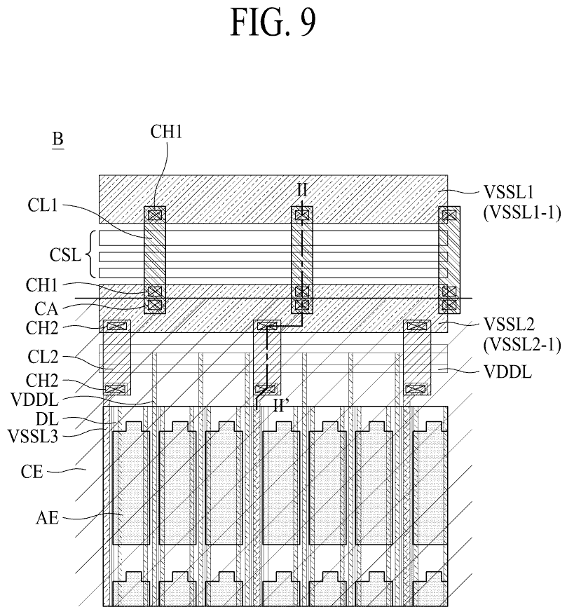

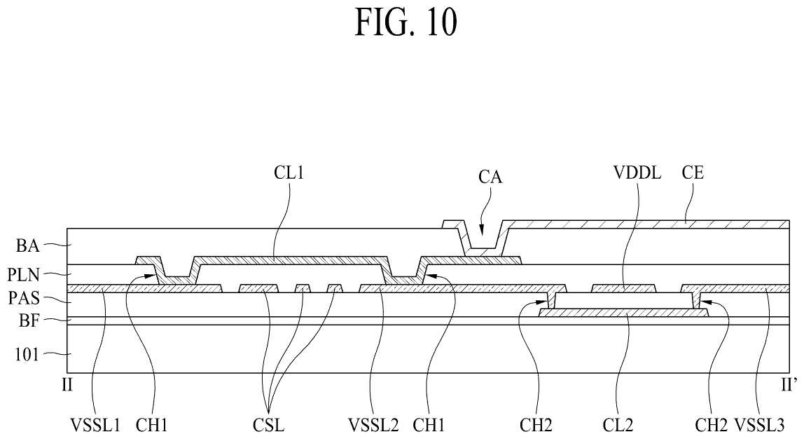

FIG. 9 illustrates region B shown in FIG. 8 according to an example embodiment of the present disclosure. FIG. 10 is a cross-sectional view taken along line II-II′ in FIG. 9 according to an example embodiment of the present disclosure.

As shown in FIGS. 9 and 10, a display panel 110 according to an example embodiment of the present disclosure may include a plurality of subpixels SP and a plurality of third low-potential voltage lines VSSL3 disposed in a display area DA, and a first low-potential voltage line VSSL1, a second low-potential voltage line VSSL2, a high-potential voltage line VDDL, and at least one control signal line CSL disposed in a non-display area NDA.

The first low-potential voltage line VSSL1 and the second low-potential voltage line VSSL2 may be formed of the same material in the same layer on a first substrate 101. For example, the first and second low-potential voltage lines VSSL1 and VSSL2 may be disposed on a passivation layer PAS. At least one control signal line CSL may be disposed between the first low-potential voltage line VSSL1 and the second low-potential voltage line VSSL2.

A first connection line CL1 may electrically connect the first low-potential voltage line VSSL1 and the second low-potential voltage line VSSL2. The first connection line CL1 may be disposed in a different layer from the first and second low-potential voltage lines VSSL1 and VSSL2 on the first substrate 101. For example, the first connection line CL1 may be disposed on a planarization layer PLN. The first connection line CL1 may be formed of the same material as a pixel electrode AE disposed on the planarization layer PLN. The first connection line CL1 may directly connect the first and second low-potential voltage lines VSSL1 and VSSL2 through a first contact hole CH1 passing through the planarization layer PLN. For example, the first connection line CL1 may intersect with at least one control signal line CSL disposed between the first and second low-potential voltage lines VSSL1 and VSSL2.

The plurality of third low-potential voltage lines VSSL3 may be disposed in the display area DA and may extend in a second direction (or Y-axis direction). The plurality of third low-potential voltage lines VSSL3 may be electrically connected to the second low-potential voltage line VSSL2. The high-potential voltage line VDDL may be disposed between the second low-potential voltage line VSSL2 and the display area DA. The plurality of third low-potential voltage lines VSSL3 may be formed of the same material as the first and second low-potential voltage lines VSSL1 and VSSL2 in the same layer on the first substrate 101. For example, the plurality of third low-potential voltage lines VSSL3 may be disposed on the passivation layer PAS.

A second connection line CL2 may electrically connect the second low-potential voltage line VSSL2 and the plurality of third low-potential voltage lines VSSL3. The second connection line CL2 may be disposed in a different layer from the first connection line CL1 on the first substrate 101. For example, the second connection line CL2 may be formed of the same material as a source/drain electrode of at least one thin film transistor disposed under the passivation layer PAS. The second connection line CL2 may directly connect the second low-potential voltage line VSSL2 and the plurality of third low-potential voltage lines VSSL3 through a second contact hole CH2 passing through the passivation layer PAS. For example, the second connection line CL2 may intersect with the high-potential voltage line VDDL disposed between the second low-potential voltage line VSSL2 and the third low-potential voltage lines VSSL3.

The non-display area NDA of the display panel 110 may further include a common electrode contact portion CA. A common electrode CE may be a common layer that entirely covers the display area DA. The common electrode CE may extend from the display area DA and may be disposed on at least a portion of the non-display area NDA. For example, the common electrode CE may be disposed to overlap at least a portion of the second low-potential voltage line VSSL2.

The first connection line CL1 may be electrically connected to the common electrode CE extended from the display area DA through the common electrode contact portion CA. The common electrode CE may be disposed on a bank portion BA, and the common electrode CE may be directly connected to the first connection line CL1 through the common electrode contact portion CA passing through the bank portion BA.

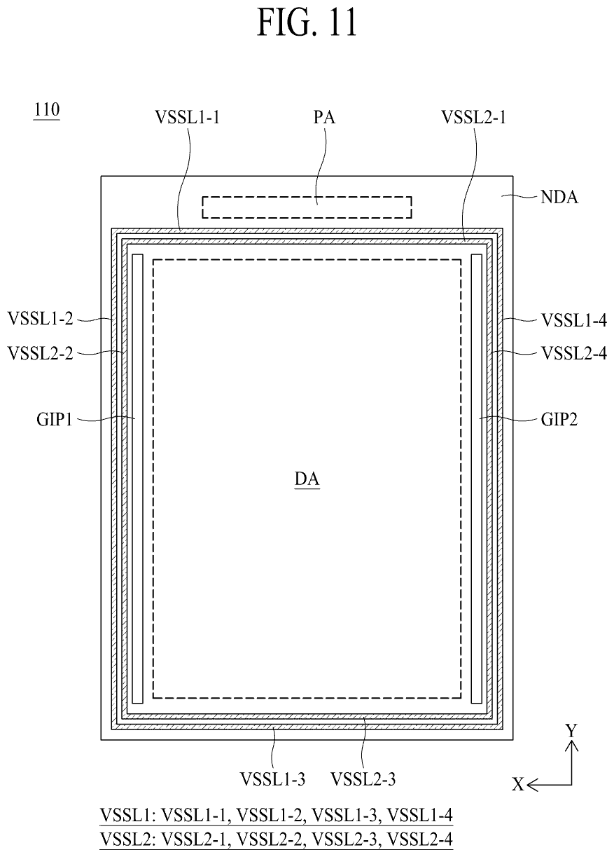

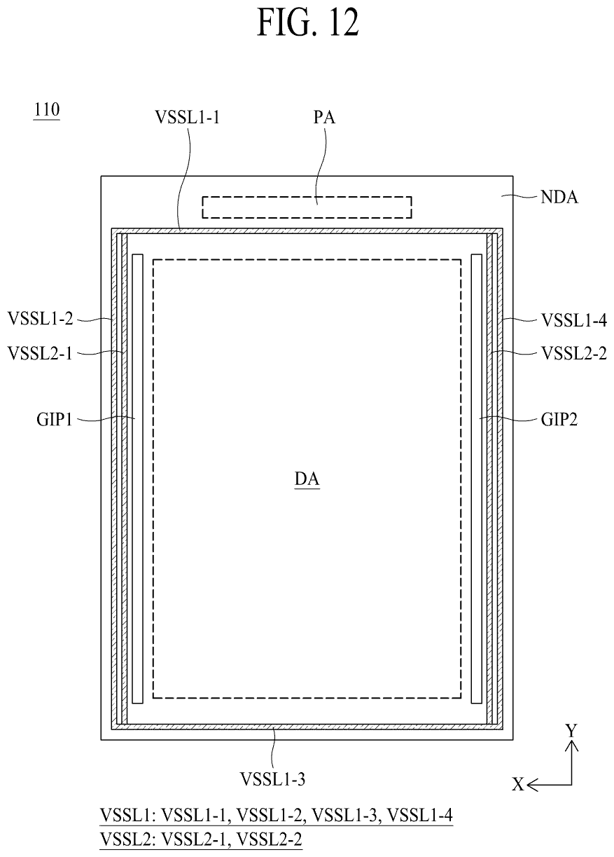

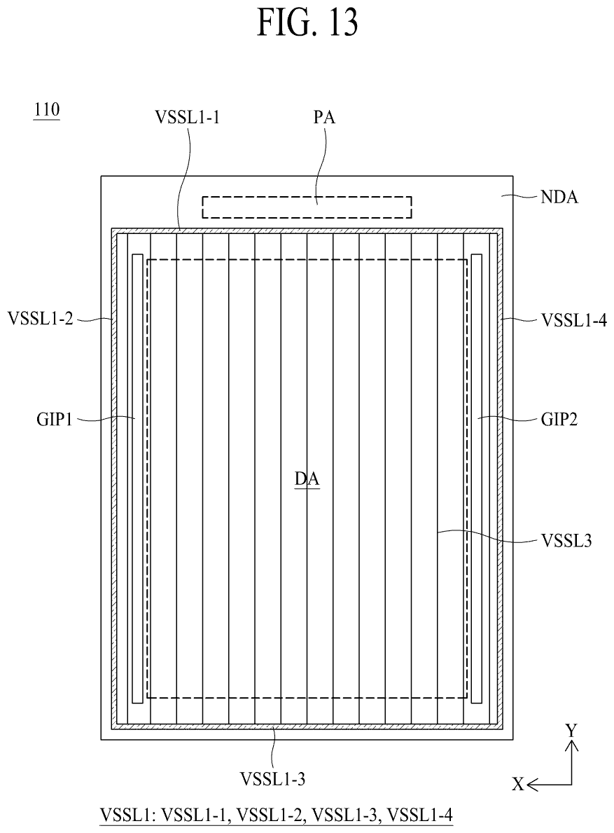

FIG. 11 illustrates a display panel according to another example embodiment of the present disclosure. FIG. 12 illustrates a display panel according to another example embodiment of the present disclosure. FIG. 13 illustrates a display panel according to another example embodiment of the present disclosure. FIGS. 11 to 13 illustrate example embodiments of the present disclosure in which a structure of the first to third low-potential voltage lines is modified in the display panel 110 described with reference to FIGS. 1 to 10. In the following description with reference to FIGS. 11 to 13, the same reference numerals will be used for the same components, except for the modified structures, and their redundant descriptions will be omitted or briefly described.

As shown in FIG. 11, a display panel 110 according to another example embodiment of the present disclosure may include a first low-potential voltage line VSSL1 and a second low-potential voltage line VSSL2. In the display area DA of the display panel 110, no separate low-potential voltage line may be disposed.

The first low-potential voltage line VSSL1 may be disposed in a non-display area NDA and may be configured in a closed loop shape surrounding the display area DA.

The second low-potential voltage line VSSL2 may be disposed in the non-display area NDA between the first low-potential voltage line VSSL1 and the display area DA, and may be configured in a closed loop shape surrounding the display area DA.

As shown in FIG. 12, a display panel 110 according to another example embodiment of the present disclosure may include a first low-potential voltage line VSSL1 and a second low-potential voltage line VSSL2. In the display area DA of the display panel 110, no separate low-potential voltage line may be disposed.

The first low-potential voltage line VSSL1 may be disposed in a non-display area NDA and may be configured in a closed loop shape surrounding the display area DA.

The second low-potential voltage line VSSL2 may be disposed in the non-display area NDA between the first low-potential voltage line VSSL1 and the gate driving circuits GIP1 and GIP2. The second low-potential voltage line VSSL2 may include a first portion VSSL2-1 extending in a second direction (or Y-axis direction) between the second portion VSSL1-2 of the first low-potential voltage line VSSL1 and the first gate driving circuit GIP1, and a second portion VSSL2-2 extending in the second direction (or Y-axis direction) between the fourth portion VSSL1-4 of the first low-potential voltage line VSSL1 and the second gate driving circuit GIP2.

The second low-potential voltage line VSSL2 may directly connect the first portion VSSL1-1 and the third portion VSSL1-3 of the first low-potential voltage line VSSL1. For example, the first portion VSSL2-1 of the second low-potential voltage line VSSL2 may directly connect between the first portion VSSL1-1 and the third portion VSSL1-3 of the first low-potential voltage line VSSL1 in the region between the second portion VSSL1-2 of the first low-potential voltage line VSSL1 and the first gate driving circuit GIP1. Also, the second portion VSSL2-2 of the second low-potential voltage line VSSL2 may directly connect between the first portion VSSL1-1 and the third portion VSSL1-3 of the first low-potential voltage line VSSL1 in the region between the fourth portion VSSL1-4 of the first low-potential voltage line VSSL1 and the second gate driving circuit GIP2.

As shown in FIG. 13, a display panel 110 according to another example embodiment of the present disclosure may include a first low-potential voltage line VSSL1 and a plurality of third low-potential voltage lines VSSL3.

The first low-potential voltage line VSSL1 may be disposed in a non-display area NDA and may be configured in a closed loop shape surrounding the display area DA.

The plurality of third low-potential voltage lines VSSL3 may be disposed in both the display area DA and the non-display area NDA. Some of the plurality of third low-potential voltage lines VSSL3 may be disposed between the first low-potential voltage line VSSL1 and the gate driving circuits GIP1 and GIP2. Most of the plurality of third low-potential voltage lines VSSL3 may be disposed to traverse the display area DA between the first portion VSSL1-1 and the third portion VSSL1-3 of the first low-potential voltage line VSSL1. Each of the plurality of third low-potential voltage lines VSSL3 may be directly connected between the first portion VSSL1-1 and the third portion VSSL1-3 of the first low-potential voltage line VSSL1.

A light emitting display apparatus according to one or more example embodiments of the present disclosure will be described below.

A light emitting display apparatus according to one or more embodiments of the present disclosure may include a substrate including a display area in which a plurality of subpixels, each comprising a pixel electrode, an emission layer, and a common electrode, are disposed, and a non-display area surrounding the display area, a gate driving circuit disposed in the non-display area and configured to drive a plurality of gate lines disposed in the display area, a first low-potential voltage line disposed in the non-display area and surrounding the display area, and a second low-potential voltage line disposed between the first low-potential voltage line and the gate driving circuit in the non-display area, the first low-potential voltage line and the second low-potential voltage line may be electrically connected to the common electrode.

According to one or more embodiments of the present disclosure, the first low-potential voltage line may have a greater line width than the second low-potential voltage line.

According to one or more embodiments of the present disclosure, the first low-potential voltage line and the second low-potential voltage line may be spaced apart from each other, and the light emitting display apparatus may further include a first connection line electrically connecting the first and second low-potential voltage lines.

According to one or more embodiments of the present disclosure, the first low-potential voltage line and the second low-potential voltage line may be formed of the same material in the same layer on the substrate, and the first connection line may be disposed in a different layer from the first and second low-potential voltage lines on the substrate.

According to one or more embodiments of the present disclosure, the first connection line may be formed of the same material as the pixel electrode in the same layer on the substrate.

According to one or more embodiments of the present disclosure, the light emitting display apparatus may further include a common electrode contact portion disposed in the non-display area, and the first connection line may be electrically connected to the common electrode extending from the display area through the common electrode contact portion.

According to one or more embodiments of the present disclosure, the plurality of gate lines may extend in a first direction of the substrate, and the second low-potential voltage line may extend in a second direction intersecting the first direction between the first low-potential voltage line and the gate driving circuit.

According to one or more embodiments of the present disclosure, the second low-potential voltage line may be disposed between the first low-potential voltage line and the display area, surrounding the display area.

According to one or more embodiments of the present disclosure, the light emitting display apparatus may further include a plurality of third low-potential voltage lines disposed in the display area and extending in the second direction, and the plurality of third low-potential voltage lines may be electrically connected to the first low-potential voltage line or the second low-potential voltage line.

According to one or more embodiments of the present disclosure, the plurality of third low-potential voltage lines may be formed of the same material as the first and second low-potential voltage lines in a same layer on the substrate.

According to one or more embodiments of the present disclosure, the light emitting display apparatus may further include a second connection line electrically connecting the first low-potential voltage line or the second low-potential voltage line and the plurality of third low-potential voltage lines, and the second connection line may be disposed in a different layer from the first connection line on the substrate.

According to one or more embodiments of the present disclosure, the plurality of gate lines may extend in a first direction of the substrate, and the first low-potential voltage line may include a first portion adjacent to a first edge of the substrate and extending in the first direction, a second portion adjacent to a second edge of the substrate perpendicular to the first edge of the substrate and extending in a second direction intersecting the first direction, a third portion adjacent to a third edge of the substrate opposite to the first edge of the substrate and extending in the first direction, and a fourth portion adjacent to a fourth edge of the substrate opposite to the second edge of the substrate and extending in the second direction.

According to one or more embodiments of the present disclosure, the first portion, the second portion, the third portion, and the fourth portion of the first low-potential voltage line may be connected to each other in a closed loop shape.

According to one or more embodiments of the present disclosure, the first portion and the third portion of the first low-potential voltage line may have a greater line width than the second portion and the fourth portion of the first low-potential voltage line.

According to one or more embodiments of the present disclosure, a corner where the first portion and the second portion of the first low-potential voltage line meet, a corner where the first portion and the fourth portion of the first low-potential voltage line meet, a corner where the third portion and the second portion of the first low-potential voltage line meet, and a corner where the third portion and the fourth portion of the first low-potential voltage line meet may have a rounded shape.

According to one or more embodiments of the present disclosure, the light emitting display apparatus may further include a pad area disposed in the non-display area adjacent to the first edge of the substrate, the pad area including a plurality of pads, and the first portion of the first low-potential voltage line may be disposed between the pad area and the display area.

According to one or more embodiments of the present disclosure, the gate driving circuit may include a first gate driving circuit adjacent to the second edge of the substrate and a second gate driving circuit adjacent to the fourth edge of the substrate, and the second low-potential voltage line may be disposed between the second portion of the first low-potential voltage line and the first gate driving circuit, and between the fourth portion of the first low-potential voltage line and the second gate driving circuit.

According to one or more embodiments of the present disclosure, the second low-potential voltage line may be electrically connected between the first portion of the first low-potential voltage line and the third portion of the first low-potential voltage line.

According to one or more embodiments of the present disclosure, the second low-potential voltage line may include a first portion parallel to the first portion of the first low-potential voltage line and disposed between the first portion of the first low-potential voltage line and the display area, a second portion parallel to the second portion of the first low-potential voltage line and disposed between the second portion of the first low-potential voltage line and the first gate driving circuit, a third portion parallel to the third portion of the first low-potential voltage line and disposed between the third portion of the first low-potential voltage line and the display area, and a fourth portion parallel to the fourth portion of the first low-potential voltage line and disposed between the fourth portion of the first low-potential voltage line and the second gate driving circuit.

According to one or more embodiments of the present disclosure, the first portion, the second portion, the third portion, and the fourth portion of the second low-potential voltage line may be connected to each other in a closed loop shape.

According to one or more embodiments of the present disclosure, the light emitting display apparatus may further include a plurality of third low-potential voltage lines disposed in the display area and extending in the second direction, and the plurality of third low-potential voltage lines may be electrically connected either between the first portion of the first low-potential voltage line and the third portion of the first low-potential voltage line or between the first portion of the second low-potential voltage line and the third portion of the second low-potential voltage line.

According to one or more embodiments of the present disclosure, the light emitting display apparatus may further include a plurality of dam portions disposed in the non-display area and surrounding an inner side of an edge of the substrate, and the plurality of dam portions may overlap at least a portion of the first low-potential voltage line and the second low-potential voltage line.

According to one or more embodiments of the present disclosure, the light emitting display apparatus may further include a buffer layer disposed on the substrate, at least one thin film transistor disposed on the buffer layer, a passivation layer covering the at least one thin film transistor, a planarization layer disposed on the passivation layer, and a bank portion disposed on the planarization layer and covering an edge of the pixel electrode, the plurality of dam portions may include a first dam and a second dam formed of at least a portion of the planarization layer and the bank portion, the first dam may overlap at least a portion of the first low-potential voltage line, and the second dam may overlap at least a portion of the second low-potential voltage line.

According to one or more embodiments of the present disclosure, the light emitting display apparatus may further include a first connection line electrically connecting the first low-potential voltage line and the second low-potential voltage line, the first low-potential voltage line and the second low-potential voltage line may be disposed on the passivation layer, and the first connection line may be disposed on the planarization layer, may be formed of the same material as the pixel electrode disposed on the planarization layer, and may directly connect the first and second low-potential voltage lines through a contact hole that passes through the planarization layer.

According to one or more embodiments of the present disclosure, the light emitting display apparatus may further include a plurality of third low-potential voltage lines disposed in the display area and extending in a second direction intersecting a first direction in which the plurality of gate lines extend, and a second connection line electrically connecting the first low-potential voltage line or the second low-potential voltage line and the plurality of third low-potential voltage lines, the plurality of third low-potential voltage lines may be disposed on the passivation layer, and the second connection line may be formed of the same material as a source/drain electrode of at least one thin film transistor disposed below the passivation layer, and may directly connect the first low-potential voltage line or the second low-potential voltage line and the plurality of third low-potential voltage lines through a contact hole that passes through the passivation layer.

The above-described features, structures, and effects of the present disclosure are included in at least one example embodiment of the present disclosure, but are not limited to only one embodiment. Furthermore, the features, structures, and effects described in at least one example embodiment of the present disclosure may be implemented through combination or modification of other embodiments by those skilled in the art. Therefore, content associated with the combination and modification of example embodiments should be construed as being within the scope of the present disclosure.

It will be apparent to those skilled in the art that various modifications and variations can be made in the present disclosure without departing from the spirit or scope of the disclosures. Thus, it is intended that the present disclosure cover the modifications and variations of this disclosure provided that they come within the scope of the appended claims and their equivalents.

What is claimed is:

1. A light emitting display apparatus, comprising:
a substrate including a display area in which a plurality of subpixels, each comprising a pixel electrode, an emission layer, and a common electrode, are disposed, and a non-display area surrounding the display area;
a gate driving circuit disposed in the non-display area and configured to drive a plurality of gate lines disposed in the display area;
a first low-potential voltage line disposed in the non-display area and surrounding the display area; and
a second low-potential voltage line disposed between the first low-potential voltage line and the gate driving circuit in the non-display area,
wherein the first low-potential voltage line and the second low-potential voltage line are electrically connected to the common electrode.

2. The light emitting display apparatus of claim 1, wherein the first low-potential voltage line has a greater line width than the second low-potential voltage line.

3. The light emitting display apparatus of claim 1, wherein:
the first low-potential voltage line and the second low-potential voltage line are spaced apart from each other; and
the light emitting display apparatus further comprises a first connection line electrically connecting the first and second low-potential voltage lines.

4. The light emitting display apparatus of claim 3, wherein:
the first low-potential voltage line and the second low-potential voltage line are formed of the same material in the same layer on the substrate; and
the first connection line is disposed in a different layer from the first and second low-potential voltage lines on the substrate.

5. The light emitting display apparatus of claim 4, wherein the first connection line is formed of the same material as the pixel electrode in the same layer on the substrate.

6. The light emitting display apparatus of claim 3, further comprising a common electrode contact portion disposed in the non-display area,
wherein the first connection line is electrically connected to the common electrode extending from the display area through the common electrode contact portion.

7. The light emitting display apparatus of claim 3, wherein:
the plurality of gate lines extend in a first direction of the substrate; and
the second low-potential voltage line extends in a second direction intersecting the first direction between the first low-potential voltage line and the gate driving circuit.

8. The light emitting display apparatus of claim 7, wherein the second low-potential voltage line is disposed between the first low-potential voltage line and the display area, surrounding the display area.

9. The light emitting display apparatus of claim 8, further comprising a plurality of third low-potential voltage lines disposed in the display area and extending in the second direction,
wherein the plurality of third low-potential voltage lines are electrically connected to the first low-potential voltage line or the second low-potential voltage line.

10. The light emitting display apparatus of claim 9, wherein the plurality of third low-potential voltage lines are formed of the same material as the first and second low-potential voltage lines in a same layer on the substrate.

11. The light emitting display apparatus of claim 10, further comprising a second connection line electrically connecting the first low-potential voltage line or the second low-potential voltage line and the plurality of third low-potential voltage lines,
wherein the second connection line is disposed in a different layer from the first connection line on the substrate.

12. The light emitting display apparatus of claim 1, wherein:
the plurality of gate lines extend in a first direction of the substrate; and
the first low-potential voltage line comprises:
a first portion adjacent to a first edge of the substrate and extending in the first direction;
a second portion adjacent to a second edge of the substrate perpendicular to the first edge of the substrate and extending in a second direction intersecting the first direction;
a third portion adjacent to a third edge of the substrate opposite to the first edge of the substrate and extending in the first direction; and
a fourth portion adjacent to a fourth edge of the substrate opposite to the second edge of the substrate and extending in the second direction.

13. The light emitting display apparatus of claim 12, wherein the first portion, the second portion, the third portion, and the fourth portion of the first low-potential voltage line are connected to each other in a closed loop shape.

14. The light emitting display apparatus of claim 12, wherein the first portion and the third portion of the first low-potential voltage line have a greater line width than the second portion and the fourth portion of the first low-potential voltage line.

15. The light emitting display apparatus of claim 12, wherein a corner where the first portion and the second portion of the first low-potential voltage line meet, a corner where the first portion and the fourth portion of the first low-potential voltage line meet, a corner where the third portion and the second portion of the first low-potential voltage line meet, and a corner where the third portion and the fourth portion of the first low-potential voltage line meet have a rounded shape.

16. The light emitting display apparatus of claim 12, further comprising a pad area disposed in the non-display area adjacent to the first edge of the substrate, the pad area including a plurality of pads,
wherein the first portion of the first low-potential voltage line is disposed between the pad area and the display area.

17. The light emitting display apparatus of claim 12, wherein:
the gate driving circuit comprises a first gate driving circuit adjacent to the second edge of the substrate and a second gate driving circuit adjacent to the fourth edge of the substrate; and
the second low-potential voltage line is disposed between the second portion of the first low-potential voltage line and the first gate driving circuit, and between the fourth portion of the first low-potential voltage line and the second gate driving circuit.

18. The light emitting display apparatus of claim 17, wherein the second low-potential voltage line is electrically connected between the first portion of the first low-potential voltage line and the third portion of the first low-potential voltage line.

19. The light emitting display apparatus of claim 17, wherein the second low-potential voltage line comprises:
a first portion parallel to the first portion of the first low-potential voltage line and disposed between the first portion of the first low-potential voltage line and the display area;
a second portion parallel to the second portion of the first low-potential voltage line and disposed between the second portion of the first low-potential voltage line and the first gate driving circuit;
a third portion parallel to the third portion of the first low-potential voltage line and disposed between the third portion of the first low-potential voltage line and the display area; and
a fourth portion parallel to the fourth portion of the first low-potential voltage line and disposed between the fourth portion of the first low-potential voltage line and the second gate driving circuit.

20. The light emitting display apparatus of claim 19, wherein the first portion, the second portion, the third portion, and the fourth portion of the second low-potential voltage line are connected to each other in a closed loop shape.

21. The light emitting display apparatus of claim 19, further comprising a plurality of third low-potential voltage lines disposed in the display area and extending in the second direction,
wherein the plurality of third low-potential voltage lines are electrically connected either between the first portion of the first low-potential voltage line and the third portion of the first low-potential voltage line or between the first portion of the second low-potential voltage line and the third portion of the second low-potential voltage line.

22. The light emitting display apparatus of claim 1, further comprising a plurality of dam portions disposed in the non-display area and surrounding an inner side of an edge of the substrate,
wherein the plurality of dam portions overlap at least a portion of the first low-potential voltage line and the second low-potential voltage line.

23. The light emitting display apparatus of claim 22, further comprising:
a buffer layer disposed on the substrate;
at least one thin film transistor disposed on the buffer layer;
a passivation layer covering the at least one thin film transistor;
a planarization layer disposed on the passivation layer; and
a bank portion disposed on the planarization layer and covering an edge of the pixel electrode,
wherein the plurality of dam portions comprise a first dam and a second dam formed of at least a portion of the planarization layer and the bank portion,
wherein the first dam overlaps at least a portion of the first low-potential voltage line, and
wherein the second dam overlaps at least a portion of the second low-potential voltage line.

24. The light emitting display apparatus of claim 23, further comprising a first connection line electrically connecting the first low-potential voltage line and the second low-potential voltage line,
wherein the first low-potential voltage line and the second low-potential voltage line are disposed on the passivation layer, and
wherein the first connection line is disposed on the planarization layer, is formed of the same material as the pixel electrode disposed on the planarization layer, and directly connects the first and second low-potential voltage lines through a contact hole that passes through the planarization layer.

25. The light emitting display apparatus of claim 24, further comprising:
a plurality of third low-potential voltage lines disposed in the display area and extending in a second direction intersecting a first direction in which the plurality of gate lines extend; and
a second connection line electrically connecting the first low-potential voltage line or the second low-potential voltage line and the plurality of third low-potential voltage lines,
wherein the plurality of third low-potential voltage lines are disposed on the passivation layer, and
wherein the second connection line is formed of the same material as a source/drain electrode of at least one thin film transistor disposed below the passivation layer, and directly connects the first low-potential voltage line or the second low-potential voltage line and the plurality of third low-potential voltage lines through a contact hole that passes through the passivation layer.
